(19) United States
(12) Patent Application Publication
(10) Pub. No.: US 2013/0118783 A1
(43) Pub. Date: May 16, 2013

(54) CIRCUIT BOARD AND STORAGE DEVICE HAVING THE SAME

(71) Applicant: Chih Sheng Huang, Jhubei City (TW)

(72) Inventor: Chih Sheng Huang, Jhubei City (TW)

(73) Assignee: Innostor Technology Corporation

(21) Appl. No.: 13/429,450

(22) Filed: Mar. 26, 2012

(30) Foreign Application Priority Data
Nov. 16, 2011 (TW) 100221567

(51) Int. Cl. H05K 1/00

(52) U.S. Cl. 174/254

(57) ABSTRACT

A circuit board includes a first pinout set of USB 2.0 standard provided on the circuit board; a second pinout set provided on the circuit board; and a flexible metal strip having a jut and four pinouts corresponding to StdA_SSRX−, StdA_SSRX+, StdA_SSTX−, and StdA_SSTX+ of USB 3.0 standard.

### CROSS-REFERENCE TO RELATED APPLICATIONS

This application claims the benefit of the filing date of Taiwan Patent Application No. 100221567, filed on 2011 Nov. 16, in the Taiwan Intellectual Property Office, the disclosure of which is incorporated herein in its entirety by reference.

### FIELD OF THE INVENTION

The invention relates to a circuit board and a storage device having the same; more particularly, to a circuit board adapted to the socket of USB 3.0 standard and a storage device having the circuit board.

### DESCRIPTION OF THE PRIOR ART

The current trend of portable electronic devices is towards compact, slim and lightweight products thanks to remarkable advances of the electronic industry. In particular, many different connection interfaces have been developed to meet the need of exchange and transmission of data and information. Among them, universal serial bus (USB) connectors are relatively popular and common for various portable electronic devices. USB was designed to standardize the connection of computer peripherals or electronic devices to personal computers, both to communicate and to supply electric power.

For a higher-speed data transmission, USB interface technology has been advanced to the specification of USB 3.0 (USB 3.0 standard). However, the pinout number of a USB 3.0 device is increased by one for the compatibility with the specification of USB 2.0 (USB 2.0 standard).

In the conventional USB connection interface, the circuit board and the USB connector are generally separate but they can be combined together by welding for example. Such configuration has a problem of larger volume and higher cost, which will be more obvious in the USB 3.0 connection interface because of the increased pinout number. Accordingly, there is a need to decrease the volume along with the cost of the USB connection interface while keeping the feature of high-speed transmission.

### SUMMARY OF THE INVENTION

In view of the forgoing problems, one object of the invention is to provide an improved circuit board where the volume and the cost of the USB connection interface is reduced without sacrificing its capacity of high-speed transmission.

In one aspect, the circuit board of the invention includes a first pinout set of USB 2.0 standard provided on the circuit board; a second pinout set provided on the circuit board; and an flexible metal strip of USB 3.0 standard, one end of which is connected to the second pinout set, the other end of which is located between the first pinout set and the second pinout set and has a jut.

In another aspect, the circuit board of the invention includes a first pinout set of USB 2.0 standard provided on the circuit board; a second pinout set provided on the circuit board and comprising four pinouts; and a plurality of flexible metal strips, one end of each of which is connected to the second pinout set, the other end of each of which is located between the first pinout set and the second pinout set and has a jut, wherein the flexible metal strips respectively correspond to StdA_SSRX−, StdA_SSRX+, StdA_SSTX−, and StdA_SSTX+ pinouts of USB 3.0 standard.

In sill another aspect, the circuit board of the invention further comprises a recess located corresponding to the flexible metal strip or the jut.

In further another aspect, the circuit board of the invention further comprises a via hole located corresponding to the flexible metal strip or the jut.

The circuit board of the invention is improved compared with the conventional one by the design of the recess and/or via hole. When plugged in or pulled out, the electronic device containing the circuit board of the invention won't be failed due to short circuit caused by the possible squeeze or compression between adjacent flexible metal strips, because the recess and/or via hole play a role in the alignment of and separation between the flexible metal strips.

The characteristics, realization and functions of the invention are disclosed in the following description with reference to the preferred exemplified embodiments and the accompanying drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a three-dimensional view of a first embodiment of the circuit board of the invention;

FIG. 2 is a three-dimensional view of a second embodiment of the circuit board of the invention;

FIG. 3 is a three-dimensional view of a third embodiment of the circuit board of the invention;

FIG. 4 is a three-dimensional view of a forth embodiment of the circuit board of the invention;

FIG. 5 is a three-dimensional view of a fifth embodiment of the circuit board of the invention;

FIG. 6 is a schematically sectional view of the recess of the circuit board of the invention;

FIG. 7 is a three-dimensional view of a sixth embodiment of the circuit board of the invention;

FIG. 8 is a three-dimensional view of a seventh embodiment of the circuit board of the invention;

FIG. 9 is a schematically sectional view of the via hole of the circuit board;

FIG. 10 is a three-dimensional view of an eighth embodiment of the circuit board of the invention;

FIG. 11 is a three-dimensional view of a ninth embodiment of the circuit board of the invention;

FIG. 12 is a schematically sectional view of the circuit board 52 of the invention;

FIG. 13 is a three-dimensional view of a tenth embodiment of the circuit board of the invention;

FIG. 14 is a three-dimensional view of an eleventh embodiment of the circuit board of the invention;

FIG. 15 is a three-dimensional view of a twelfth embodiment of the circuit board of the invention;

FIG. 16 is a three-dimensional view of a thirteenth embodiment of the circuit board of the invention;

FIG. 17 is a three-dimensional view of a fourteenth embodiment of the circuit board of the invention;

FIG. 18 is a three-dimensional view of a fifteenth embodiment of the circuit board of the invention;

FIG. 19 is a three-dimensional view of a sixteenth embodiment of the circuit board of the invention;

FIG. 20 is a schematic view of the storage device 90 of the invention; and

FIG. 21 is a schematic view of the storage device 91 of the invention.

### DETAILED DESCRIPTION OF THE INVENTION

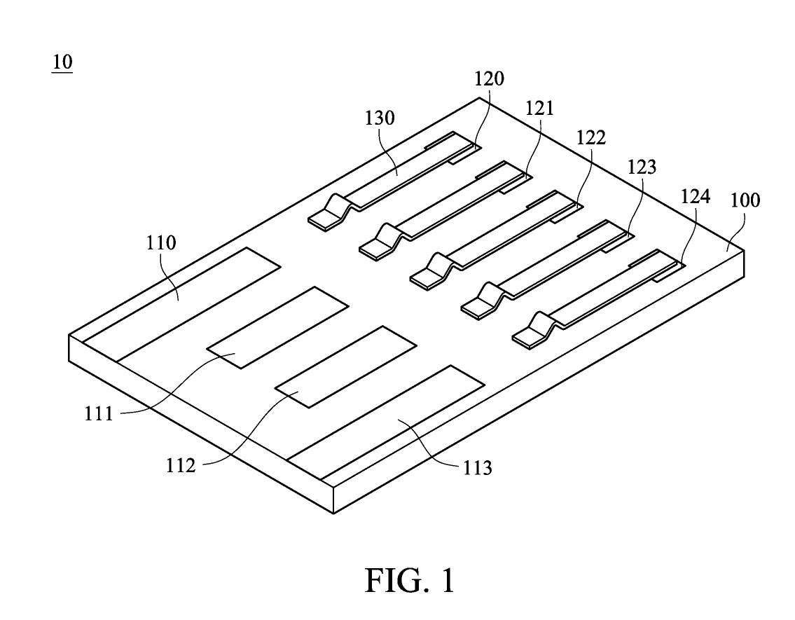

FIG. 1 is a three-dimensional view of a first embodiment of the circuit board 10 of the invention. The circuit board 10 of the invention includes a first pinout set 11, a second pinout set 12 and a flexible metal strip 130 provided respectively on the circuit board 10. The first pinout set 11 has a specification of USB 2.0 (USB 2.0 standard), while the flexible metal strip 130 has a specification of USB 3.0 (USB 3.0 standard). One end of the flexible metal strip 130 is connected to the second pinout set 12, and the other end thereof includes a jut and is located between the first and the second pinout sets 11 and 12.

It is to be noted that in this embodiment the jut of the flexible metal strip 130 has a bend shape as shown in FIG. 1. However, this is illustrative but not limitative; that is, the shape of the jut may be determined as desired provided that the flexible metal strip can be more readily in contact with the contact (junction) of USB socket. For example, the jut may be the one formed by cropping or spot welding or soldering, i.e. a cropped, spot welding or solder jut. Besides, the flexible metal strip 130 and the jut thereof are both elastic and bendable. So, when plugged into a compatible USB socket, the circuit board of the invention is capable of changing the shape of the jut correspondingly, thereby facilitating the connection and achieving the secure function.

The circuit board 10 of the invention is designed to be compatible with both the USB 2.0 and USB 3.0 standards for facilitating the user's operation by means of the first and the second pinout sets 11 and 12. Further, together with the design of the flexible metal strip 130 provided on the circuit board 10, the connector pinouts of a conventional USB connector can be integrated onto the circuit board 10. In the conventional USB connection interface, the circuit board has to be additionally connected with a USB connector outside the circuit board itself, while it's unnecessary for the circuit board of the invention. In brief, the circuit board 10 of the invention has the merits of simplified design of circuits, and reduced occupied space and cost without sacrificing the feature of high-speed transmission of the USB connection interface.

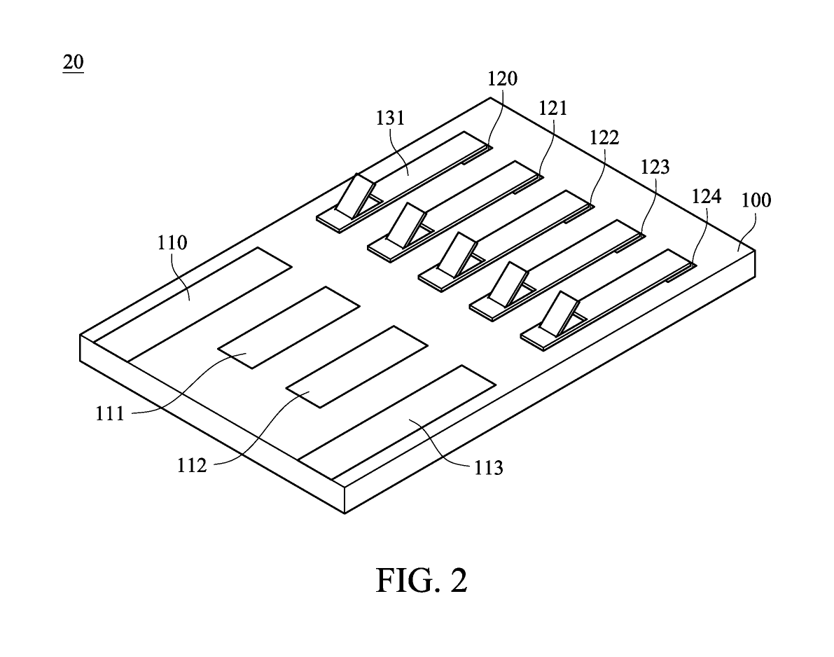

FIG. 2 is a three-dimensional view of a second embodiment of the circuit board 20 of the invention. The configuration of the circuit board 20 is similar to that of the circuit board 10 except the jut of the flexible metal strip 131 of the former is formed by cutting and then bending part of the flexible metal strip 131. For comparison, in the first embodiment (FIG. 1), the jut is formed by bending part of the flexible metal strip 130 itself directly.

It is to be noted that the profile of the cut portion used for forming the jut of the flexible metal strip 131 of the circuit board 20 in the second embodiment may be determined as desired such as a triangle, a square, or a rectangle. However, the profiles listed above are only illustrative and will not limit the scope of the invention, and the structure of the flexible metal strip 131 of the circuit board 20 could be modified as required.

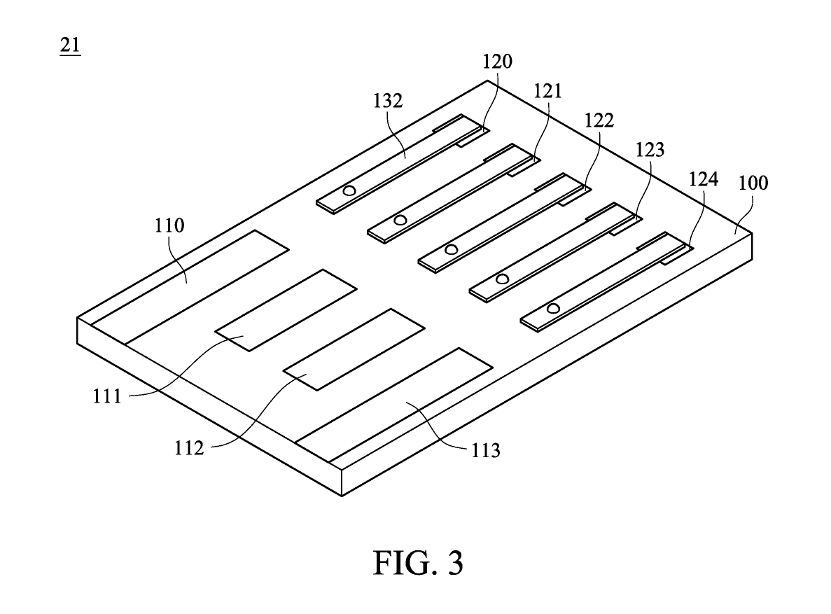

FIG. 3 is a three-dimensional view of a third embodiment of the circuit board 30 of the invention. The configuration of the circuit board 30 is similar to that of the circuit board 10 except the jut of the former is formed as a salient point by spot welding rather than bending part of the flexible metal strip 132 itself directly (see FIG. 1). Similarly, the structure of the flexible metal strip 132 of the circuit board 30 in the third embodiment is only illustrative and will not limit the scope of the invention.

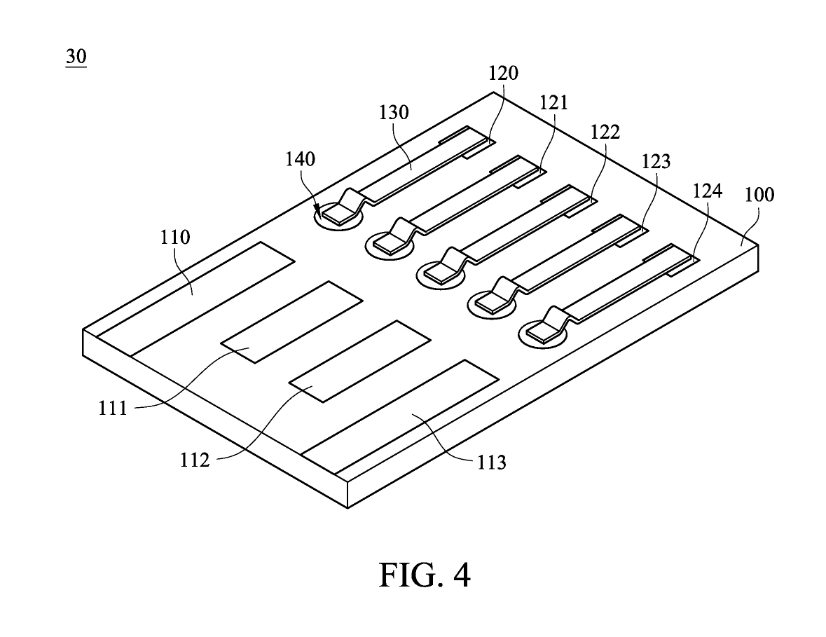

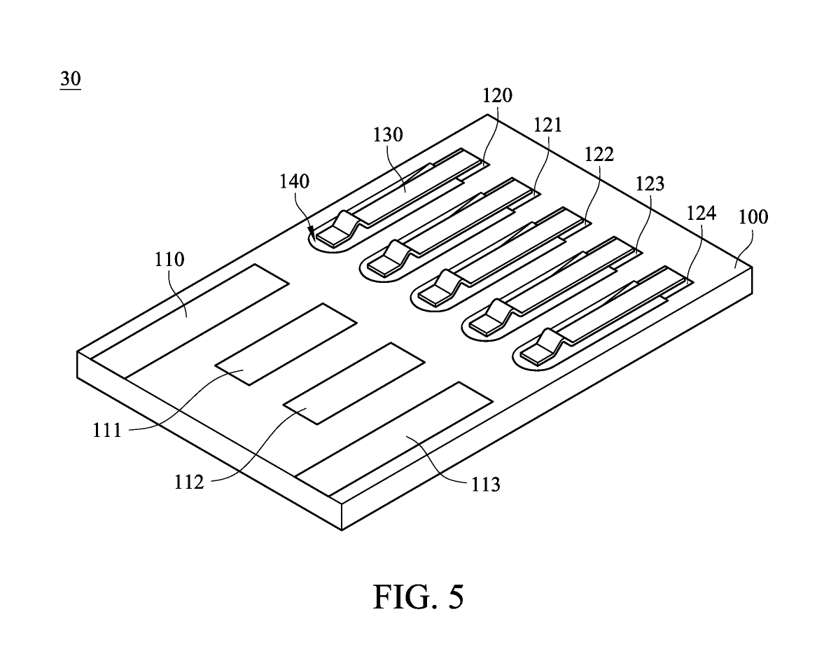

FIGS. 4 and 5 are respectively three-dimensional views of a forth and a fifth embodiments of the circuit boards 40 and 41 of the invention. Both of the circuit boards 40 and 41 are similar in the configuration to the circuit boards 10-30 except that the former two further include a recess 140 individually.

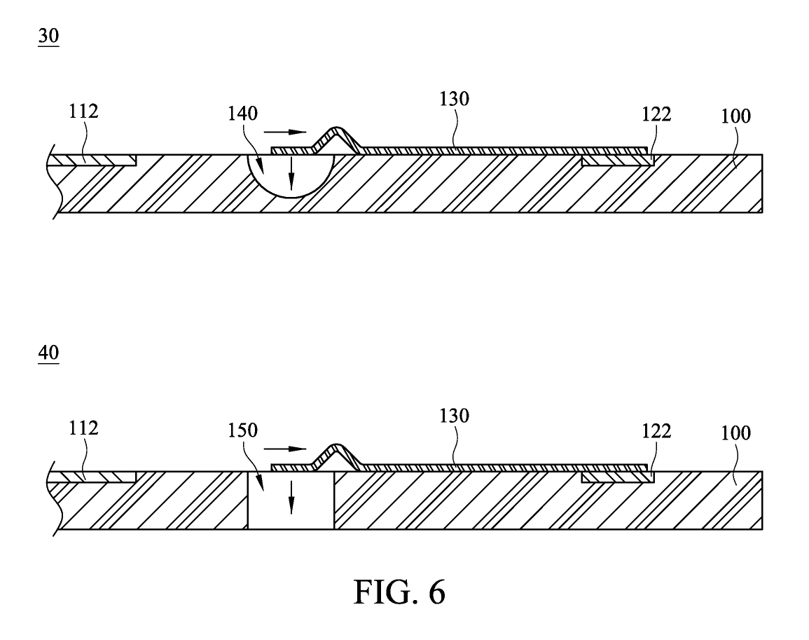

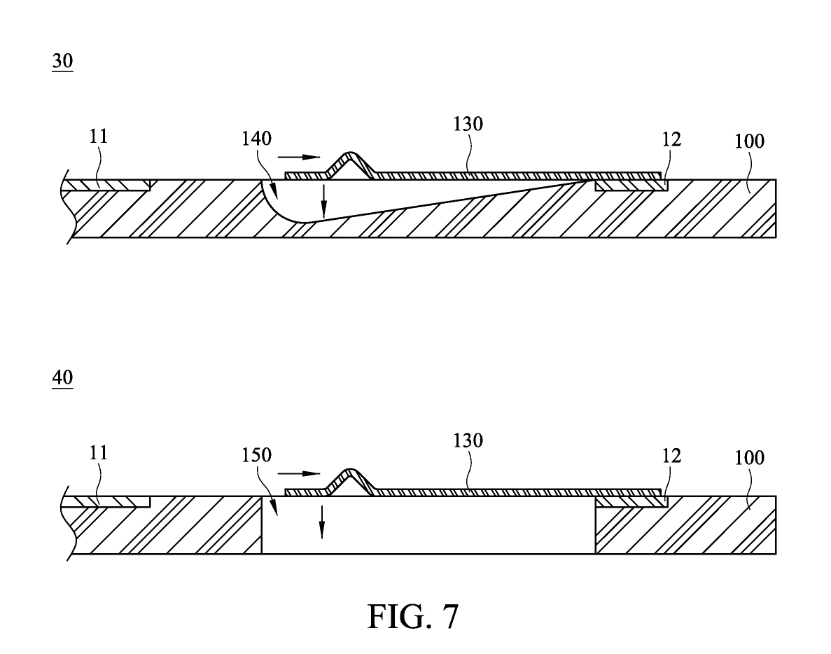

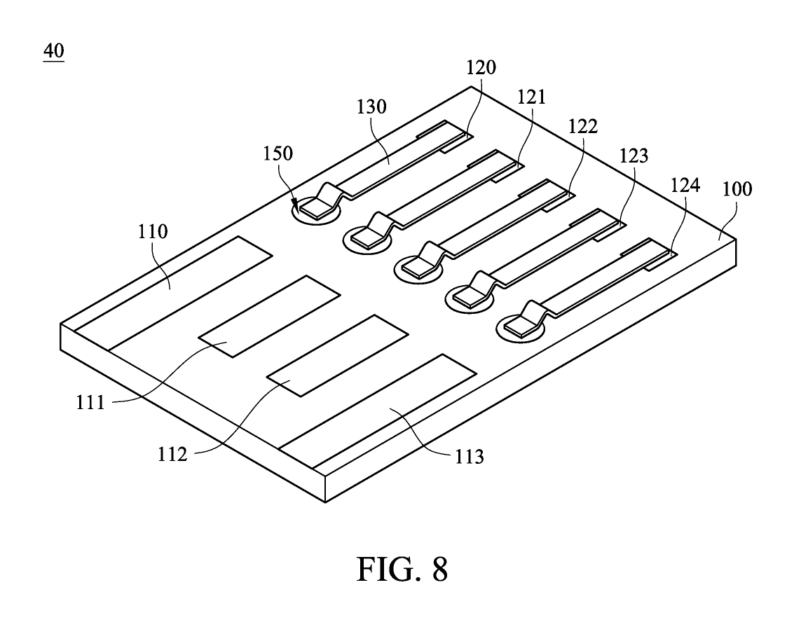

FIG. 6 is a schematically sectional view of the recess 140 of the circuit board 40 or 41. The recess 140 is configured on the circuit board with the position and size corresponding to either the entire flexible metal strip (as shown in FIG. 5 or 8) or simply the jut (as shown in FIG. 4 or 7) for assisting in the automatic alignment of and separation between the flexible metal strips 130, 131 or 132. In more detail, it can prevent the impact and even short circuit caused by the possible squeeze or compression between adjacent flexible metal strips 130, 131 or 132 when connected to the USB socket.

It is to be noted that the structure of the recess 140 of the circuit board 40 or 41 may be determined as desired or according to the structure of the flexible metal strip 130, 131 or 132. For example, the profile of the recess 140 could be a hemisphere, ellipsoid, cube or cuboid. However, it will be appreciated that the profiles described here are not intended to be limitative but illustrative.

FIGS. 7 and 8 are respectively three-dimensional views of a sixth and a seventh embodiments of the circuit boards 50 and 51 of the invention. Both of the circuit boards 50 and 51 are similar in the configuration to the circuit boards 10-30 except that the former two further include a via hole 150 individually.

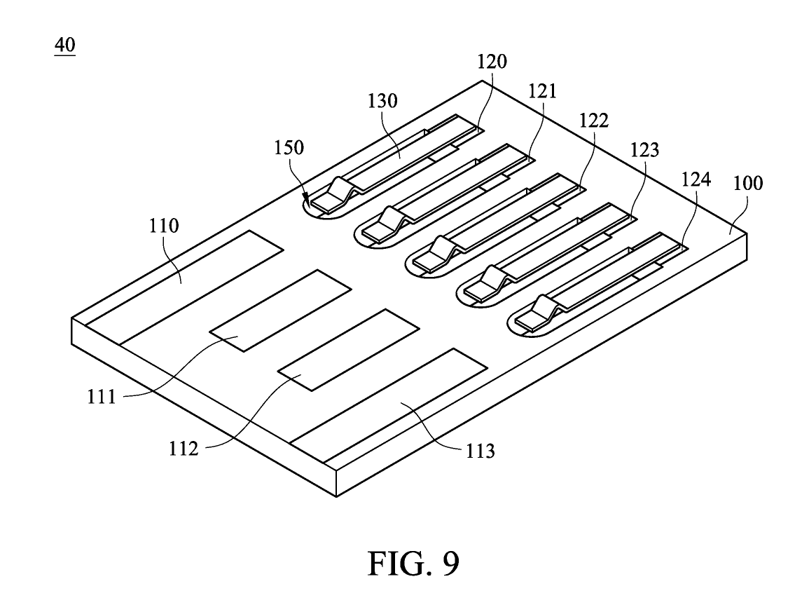

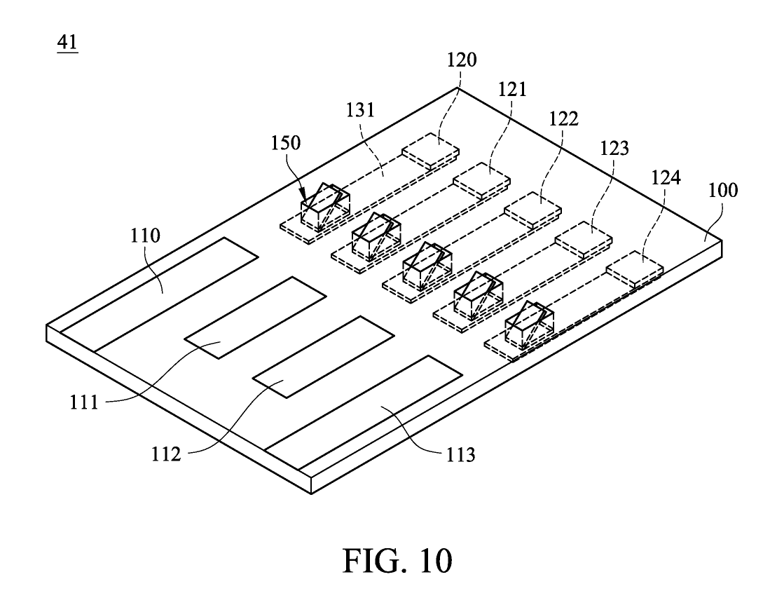

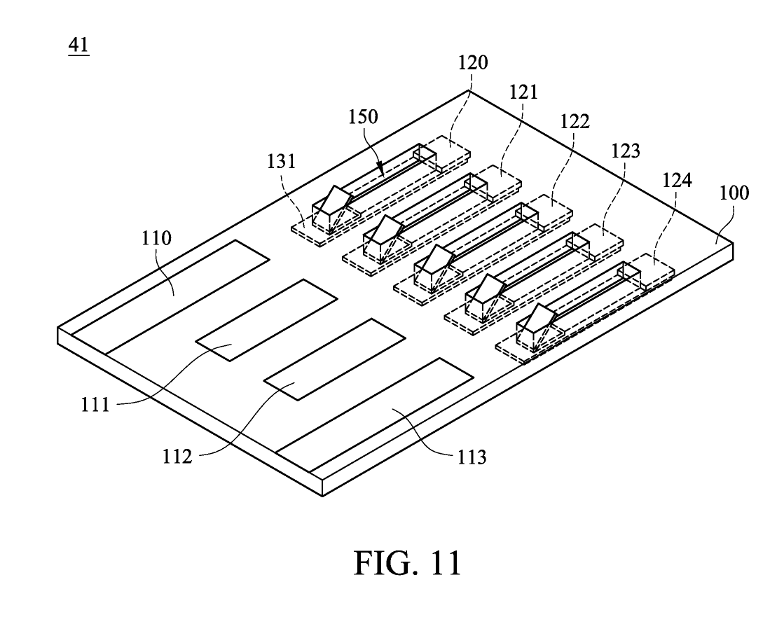

FIG. 9 is a schematically sectional view of the via hole 150 of the circuit board 50 or 51. The via hole 150 is configured on the circuit board with the position and size corresponding to either the entire flexible metal strip (as shown in FIG. 8 or 11) or simply the jut (as shown in FIG. 7 or 10) for the automatic alignment of and separation between the flexible metal strips 130, 131 or 132. In more detail, it can also prevent the impact and even short circuit caused by the possible squeeze or compression between adjacent flexible metal strips 130, 131 or 132 when connected to the USB socket.

The structure of the via hole 150 of the circuit board 50 or 51 may be determined as desired. For example, the profile of the via hole 150 could be a cylinder, elliptic cylinder, cube or cuboid. However, it is to be noted that the profiles described here are not intended to be limitative but illustrative.

FIGS. 10 and 11 are respectively three-dimensional views of an eighth and a ninth embodiments of the circuit boards 52 and 53 of the invention. Both of the circuit boards 52 and 53 are similar in the configuration to the circuit boards 50 and 51 except that the second pinout set 12 and the flexible metal strip 130, 131 or 132 are provided on the other surface of the circuit board where the first pinout set 11 is not located in case the via hole 150 is arranged.

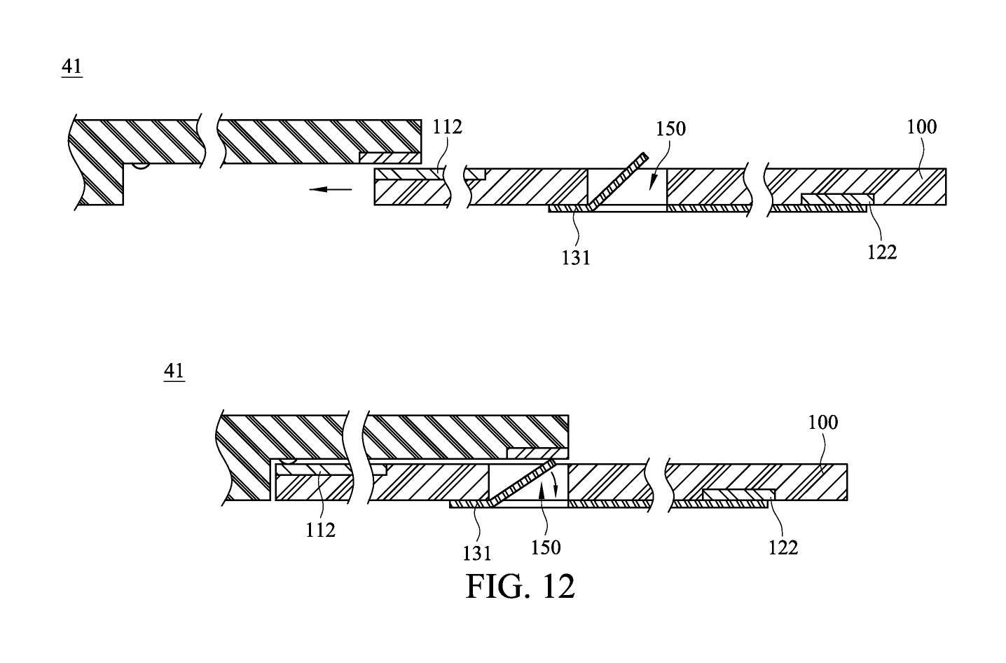

FIG. 12 is a schematically sectional view of the circuit board 52 or 53 of the invention. It indicates that the flexible metal strip 130, 131, or 132 could still touch the respective pinouts of the USB socket successfully by using the juts which penetrate through the via holes 150 thereof.

The connector pinouts of the conventional USB connector are integrated on the circuit boards 52 and 53 both having a specification of the connection interface compatible with USB 2.0 and USB 3.0 standards. Therefore, the circuit boards 52 and 53 also incorporate the functions of automatic alignment of and separation between the flexible metal strips 130, 131 or 132. In addition, the fact that some circuits are arranged on the other side of the circuit board in this embodiment demonstrates a more flexible and diverse circuit layout or design.

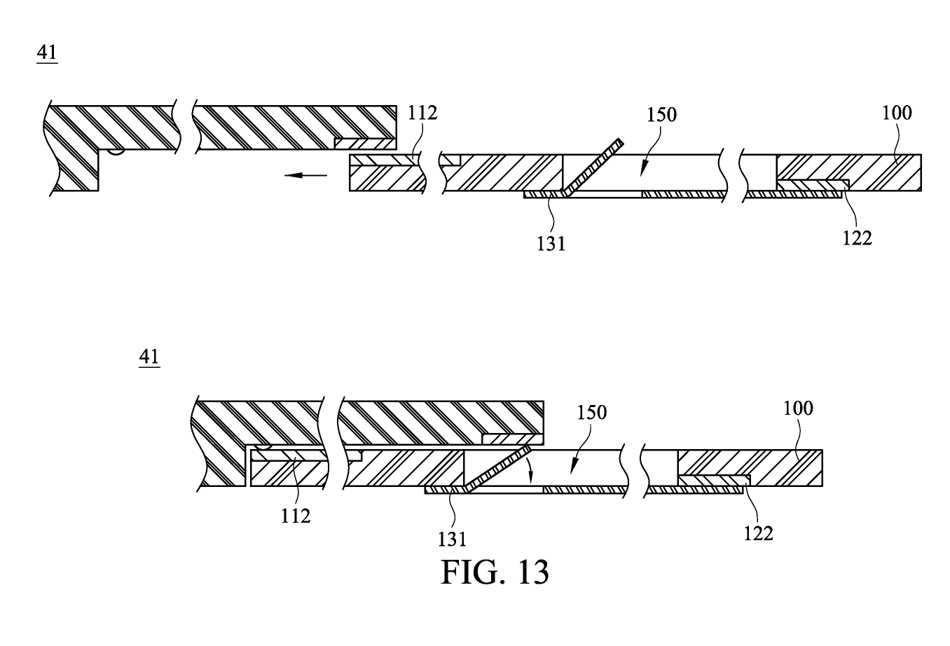

FIG. 13 is a three-dimensional view of a tenth embodiment of the circuit board 60 of the invention. The configuration of the circuit board 60 is similar to that of the circuit board 10 except the second pinout set 12 thereof is provided merely with four pinouts of USB 3.0, StdA_SSRX− 120, StdA_SSRX+ 121, StdA_SSTX− 123, and StdA_SSTX+ 124 but without GND_DRAIN 122 pinout.

Since the circuit board 60 is designed to be additionally compatible with the USB 2.0 standard, the GND pinout in the first pinout set 11 fit to the USB 2.0 standard will be plugged in and then electrically connected to the ground pinout of the corresponding USB socket when the circuit board 60 is connected thereto. In the common electronic device and USB connection interface, only one single ground level is used as the reference voltage level. So, the circuit board 60 can still work without any problem even if the pinout in the second pinout set 12 corresponding to GND_DRAIN 122 is removed, since USB 2.0 and USB 3.0 share one single ground level. That is, when the circuit board 60 is plugged in the corresponding USB socket, the pinout corresponding to the ground level (GND) in the first pinout set 11 corresponding to the USB 2.0 connection interface will be electrically connected to the ground pinout in the circuit board 60 whose voltage level is exactly equal to what USB 2.0 and USB 3.0 share.

The circuit board 60 free of the pinout corresponding to GND_DRAIN 122 is advantageous because more space is available for circuit design or arrangement and thereby the manufacturing cost is reduced.

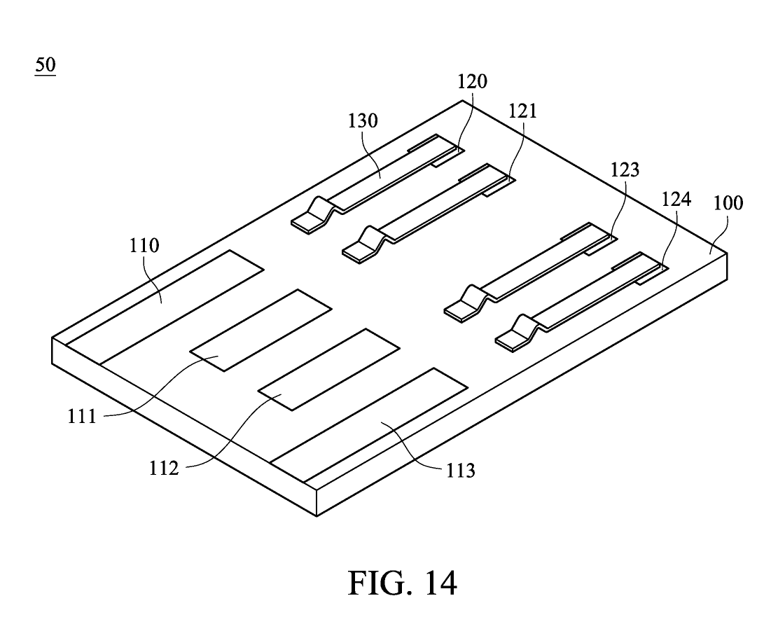

FIG. 14 is a three-dimensional view of an eleventh embodiment of the circuit board 61 of the invention. The configuration of the circuit board 61 is similar to that of the circuit board 60 except the jut of the flexible metal strip 131 of the former is formed by cutting and then bending part of the flexible metal strip 131. For comparison, in the first embodiment (FIG. 1), the jut is formed by bending part of the flexible metal strip 130 itself directly.

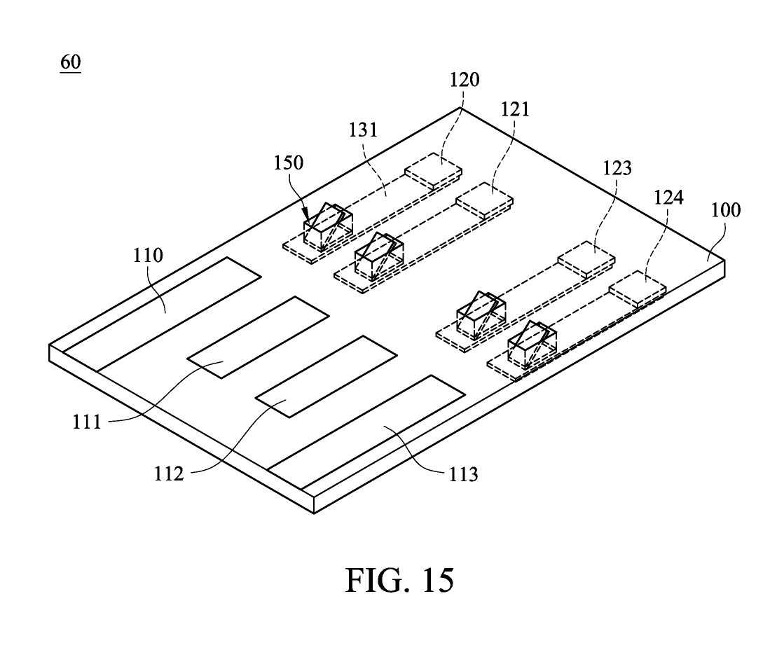

FIG. 15 is a three-dimensional view of a twelfth embodiment of the circuit board 62 of the invention. The configuration of the circuit board 62 is similar to that of the circuit board 60 except the jut of the former is formed as a salient point by spot welding rather than bending part of the flexible metal strip 132 itself directly (see FIG. 1).

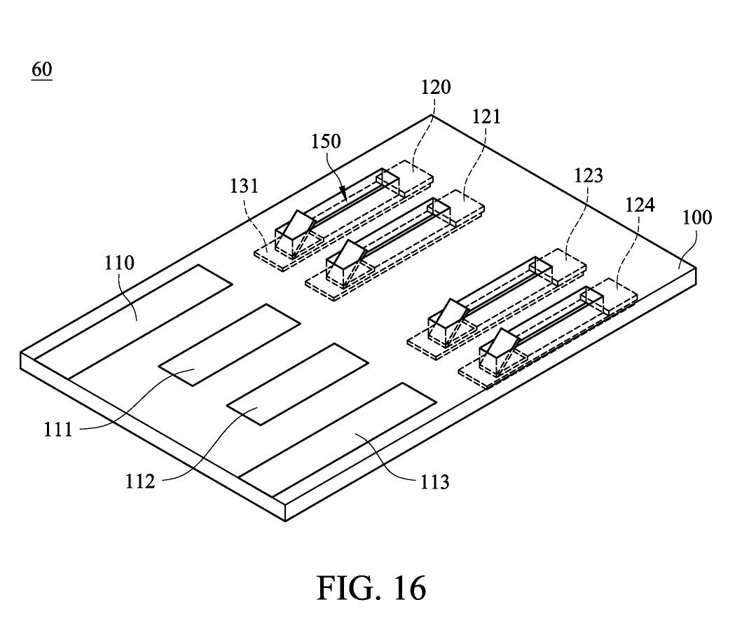

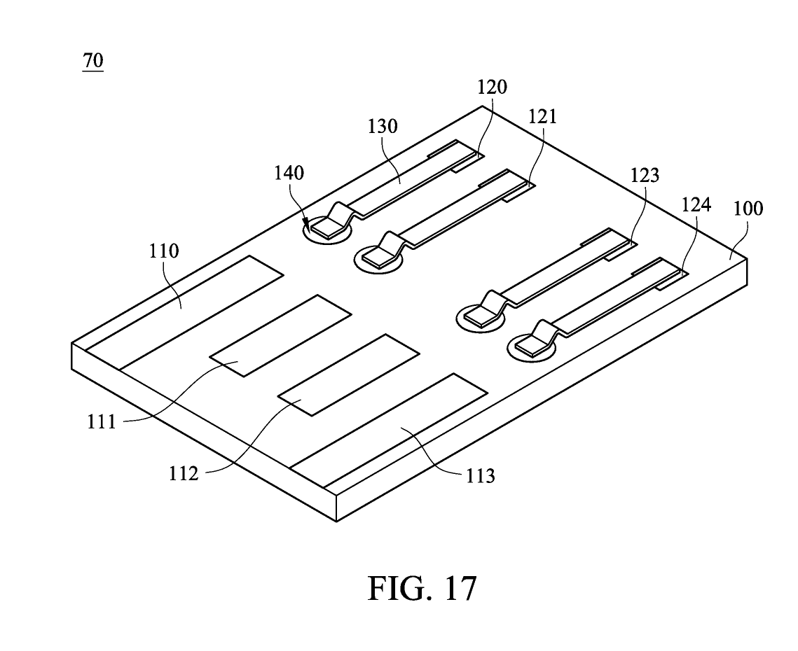

FIGS. 16 and 17 are respectively three-dimensional views of a thirteenth and a fourteenth embodiments of the circuit boards 70 and 71 of the invention. Both of the circuit boards 70 and 71 are similar in the configuration to the circuit boards 60-62 except that the former two further include a recess 140 individually. Since the function and effect of the circuit boards 70 and 71 are like those of the circuit boards 40 and 41, the details thereof will be omitted here.

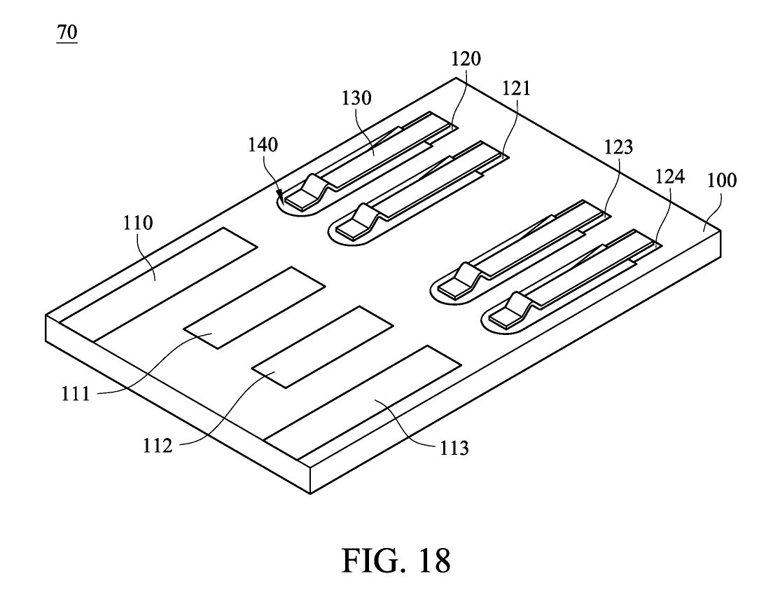

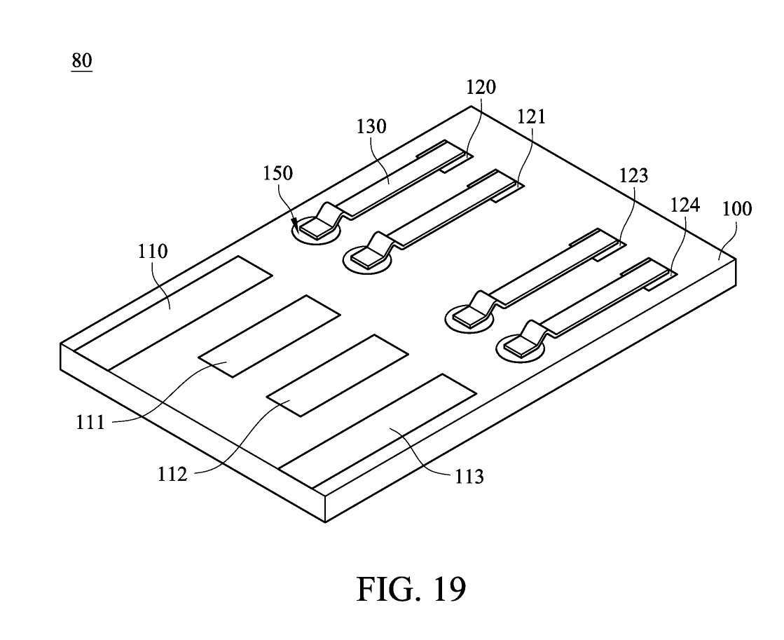

FIGS. 18 and 19 are respectively three-dimensional views of a fifteenth and a sixteenth embodiments of the circuit boards 80 and 81 of the invention. Both of the circuit boards 80 and 81 are similar in the configuration to the circuit boards 60-62 except that the former two further include a via hole 150 individually. Since the function and effect of the circuit boards 80 and 81 are like those of the circuit boards 50 and 51, the details thereof will be omitted here too.

It is to be noted that the flexible metal strip 130, 131, or 132 in the first, second, or third embodiment respectively may be used as the circuit boards 80 and 81. However, the configuration of the flexible metal strip of the circuit boards 80 and 81 may be modified as desired without departing from the spirit of the invention.

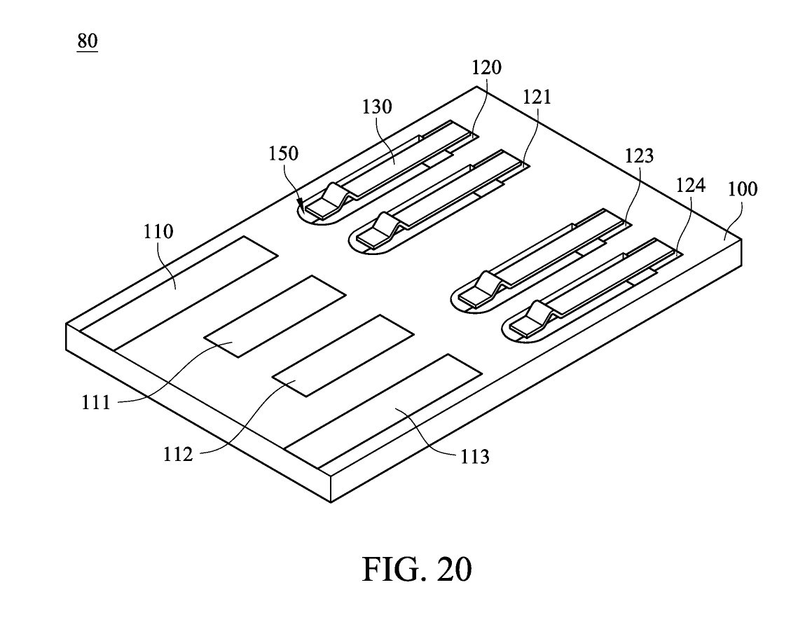

FIG. 20 is a schematic view of the storage device 90 of the invention. The storage device 90 includes a circuit board 10, a storage unit 200, and a control unit 300. For example, the storage unit 200 could be a flash memory, random access memory (RAM), or other non-volatile memories, and the control unit 300 could be a micro-controller. The circuit board 10 has a first pinout set 11 and a second pinout set 12 both electrically connected to the control unit 300 that is electrically connected to the storage unit 200 and responsible for the data access to the storage unit 200.

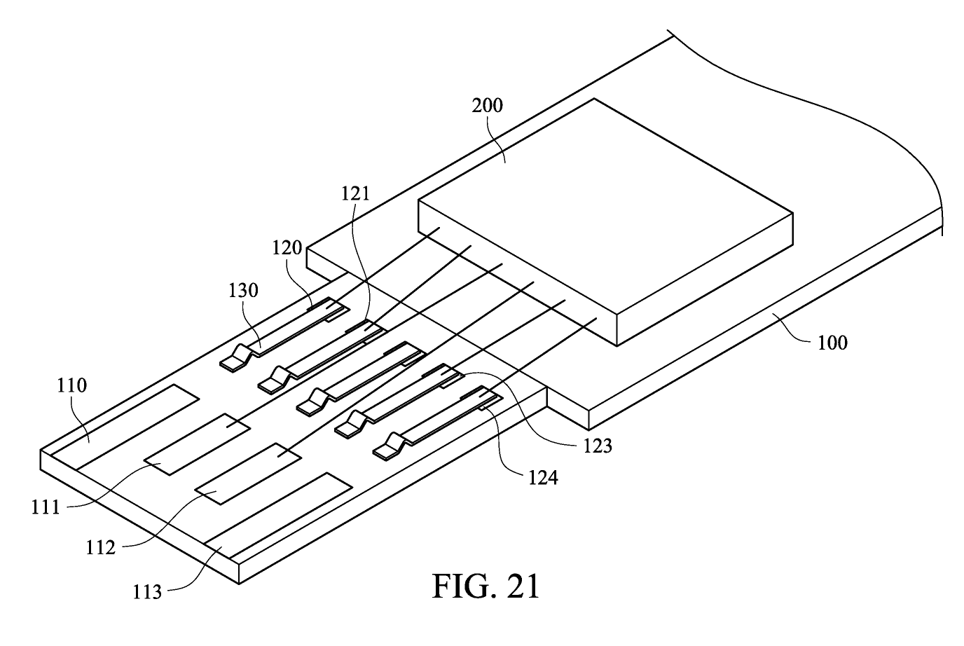

FIG. 21 is a schematic view of the storage device 91 of the invention. The storage devices 90 and 91 are basically the same, while the difference therebetween lies in the GND_DRAIN pinout. As the storage device 91 has no GND_DRAIN pinout in the inside circuit board, the electrical wiring design in the circuit board is allowed to be more flexible and diverse.

From the above description of the invention, it is manifest that various techniques can be used for implementing the concepts of the invention without departing from the scope thereof. Moreover, while the invention has been described with specific reference to certain embodiments, a person of ordinary skills in the art would recognize that changes can be made in form and detail without departing from the spirit and the scope of the invention. The described embodiments are to be considered in all respects as illustrative and not restrictive. It is intended that the scope of the invention is defined by the appended claims.

What is claimed is:

1. A circuit board comprising:
a first pinout set of USB 2.0 standard provided on the circuit board;
a second pinout set provided on the circuit board and comprising four pinouts; and
a plurality of flexible metal strips, one end of each of which is connected to the second pinout set, the other end of each of which is located between the first pinout set and the second pinout set and has a jut, the flexible metal strips respectively corresponding to StdA_SSRX−, StdA_SSRX+, StdA_SSTX−, and StdA_SSTX+ pinouts of USB 3.0 standard.

2. The circuit board according to claim 1, wherein the second pinout set further comprises one more pinout, and one more flexible metal strip corresponding to a GND_DRAIN pinout of USB 3.0 standard is mounted on the circuit board.

3. The circuit board according to claim 1, wherein the jut is a bend jut, a cropped jut or a solder jut.

4. The circuit board according to claim 3, wherein the circuit board further comprises a recess or a via hole located corresponding to the flexible metal strip or the jut.

5. A storage device characterized by comprising a circuit board, the circuit board comprising:
a first pinout set of USB 2.0 standard provided on the circuit board;
a second pinout set provided on the circuit board; and
a flexible metal strip of USB 3.0 standard, one end of which is connected to the second pinout set, the other end of which is located between the first pinout set and the second pinout set and has a jut.

6. The storage device according to claim 5, wherein the jut is a bend jut, a cropped jut or a solder jut.

7. The storage device according to claim 6, wherein the circuit board further comprises a recess or a via hole located corresponding to the flexible metal strip or the jut.

8. A storage device characterized by comprising a circuit board, and the circuit board comprising:
a first pinout set of USB 2.0 standard provided on the circuit board;
a second pinout set provided on the circuit board and comprising four pinouts; and
a plurality of flexible metal strips, one end of each of which is connected to the second pinout set, the other end of each of which is located between the first pinout set and the second pinout set and has a jut, the flexible metal strips respectively corresponding to StdA_SSRX−, StdA_SSRX+, StdA_SSTX−, and StdA_SSTX+ pinouts of USB 3.0 standard.

9. The storage device according to claim 8, wherein the second pinout set further comprises one more pinout, and one more flexible metal strip corresponding to a GND_DRAIN pinout of USB 3.0 standard is mounted on the circuit board.

10. The storage device according to claim 8, wherein the jut is a bend jut, a cropped jut or a solder jut.

11. The storage device according to claim 10, wherein the circuit board further comprises a recess or a via hole located corresponding to the flexible metal strip or the jut.
